(19) United States
(12) Patent Application Publication
(10) Pub. No.: US 2009/0309636 A1
(43) Pub. Date: Dec. 17, 2009

(54) Triangle wave generator and switching regulator

(75) Inventor: Yoshitaka Nishigata, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/453,339

(22) Filed: May 7, 2009

(30) Foreign Application Priority Data
Jun. 13, 2008 (JP) 2008-154835

(51) Int. Cl. H03K 4/06

(52) U.S. Cl. 327/140

(57) ABSTRACT

A switching regulator maintain an output voltage substantially constant by using a first comparator that compares a power supply voltage with the output voltage of the switching regulator, a triangle wave formation circuit that changes amplitude of a triangle wave according to an output signal of the first comparator, and a triangle wave generated by the triangle wave formation circuit.

### BACKGROUND

1. Field of the Invention

The present invention relates to a triangle wave generator that generates a triangle wave and, particularly, to a triangle wave generator to be used in a switching regulator that outputs a voltage or the like and a switching regulator using the same.

2. Description of Related Art

A switching regulator is generally known as a circuit for outputting a constant voltage. In the switching regulator, a current is intermittently supplied to a coil connected to a load using a switching element, such as a MOS transistor, whose conduction state is controlled by a switching pulse. In the switching regulator, an output voltage can be obtained by a self-electromotive force of the coil and rectification using a diode and a capacitor.

However, if a power supply voltage and an output voltage are close to each other in the switching regulator, a differential voltage is low and pulse skip occurs unless using a high-speed error amplifier and a high-speed PWM comparator. This causes an issue that the switching time becomes longer and the ripple increases.

To address the above issue, Japanese Unexamined Utility Model Publication No. 61-65883 (Kato) discloses a method of reducing the switching pulse width by inputting a sharp triangle wave to a PWM comparator. FIG. 7 shows the configuration of the switching regulator according to prior art which is described in Kato. Referring to FIG. 7, the switching regulator according to prior art includes a triangle wave generator 1, a PWM comparator 2, an error amplifier 3, an output circuit 4 and a load 5.

The output of the triangle wave generator 1 is connected to the + input of the PWM comparator 2. The − input of the PWM comparator 2 is connected to the output of the error amplifier 3. The output of the PWM comparator 2 is connected to the input side of the output circuit 4. The output side of the output circuit 4 is connected to the load 5 and the input of the error amplifier 3.

If the voltage at a node OUT, which is the output of the switching regulator shown in FIG. 7, becomes lower, the output of the error amplifier 3 increases and thus the PWM comparator 2 outputs High (Hi). The output circuit 4 thereby performs switching operation and the output at the node OUT increases.

The triangle wave generator which is taught by Kato is described hereinafter with reference to FIG. 8. One end of a capacitor C1, the other end of which is connected to GND, is connected to a discharge path, the + input of a comparator 11 and the collector of a PNP bipolar transistor Q4. The collector of a PNP bipolar transistor Q3 is connected to the collector of an NPN transistor Q1 and the collector of an NPN transistor Q2. The PNP bipolar transistors Q3 and Q4 form a current mirror.

The emitter of the NPN transistor Q1 is connected to one end of a resistor R1, the other end of which is connected to GND. The base of the NPN transistor Q1 is connected to the anode of a diode D1 and one end of a resistor 16, the other end of which is connected to a power supply 13. The cathode of the diode D1 is connected to the anode of a diode D2, the cathode of which is connected to GND.

Further, the emitter of the NPN transistor Q2 is connected to one end of a resistor R2, the other end of which is connected to GND. The base of the NPN transistor Q2 is connected to the anode of a diode D3 and the output of the comparator 11. The cathode of the diode D3 is connected to the anode of a diode D4, the cathode of which is connected to GND. The − input of the comparator 11 is connected to a midpoint between a resistor R3, the other end of which is connected to Vref and a resistor R4, the other end of which is connected to GND. The resistor R3 is connected to Vref.

FIG. 9 shows a waveform that is generated by the above-described triangle wave generator. A node that is connected to the + input of the comparator 11 where a triangle wave is generated is referred to as the node M. It is assumed that the node M is in the state of being completely discharged by the discharge path.

Because the output of the comparator 11 is Hi, the NPN transistor Q2 operates and a collector current I2 flows therethrough. Further, because the NPN transistor Q1 is always in operation, a collector current I1 flows therethrough. Because the PNP bipolar transistors Q3 and Q4 form a current mirror, a collector current Io of the PNP bipolar transistor Q4 to charge the capacitor C1 is represented by the following expression (1):

Io=I1+I2 (1)

The potential at the capacitor C1 increases as represented by the following expression (2):

ΔV=Io×t÷C1 (2)

If the potential at the capacitor C1 becomes higher than the − input of the comparator 11, the output of the comparator 11 changes from Hi to Lo, and the following current Io′ flows as the collector current Io of the PNP bipolar transistor Q4:

Io′=I1 (3)

Accordingly, the triangle wave as shown in FIG. 9 is generated at the node M.

FIG. 10 is a view to describe an issue. In FIG. 10, A→B→C→D→E indicates a sharp triangle wave which is described in Kato. On the other hand, A′→C→E′ indicates a typical triangle wave in the same cycle as the sharp triangle wave.

Comparing the case where the sharp triangle wave A→B→C→D→E is input and the case where the typical triangle wave A′→C→E′ is input respectively as the triangle wave of the switching regulator described above, because the triangle wave A→B→C→D→E has larger amplitude, the total gain of the switching regulator is lower. Therefore, even when a difference between the output voltage and the power supply voltage is large enough, the total gain of the switching regulator is low, causing degradation of the output voltage accuracy and the transient response characteristics.

### SUMMARY

The present inventor has found a problem that in the switching regulator using the triangle wave generator that generates a sharp triangle wave, the total gain of the switching regulator is low even when a difference between the output voltage and the power supply voltage is large enough, causing degradation of the output voltage accuracy and the transient response characteristics.

A first exemplary aspect of an embodiment of the present invention is a switching regulator that includes a first comparator to compare a power supply voltage with an output voltage of the switching regulator, and a triangle wave formation circuit to change amplitude of a triangle wave according to an output signal of the first comparator, wherein the output voltage is maintained substantially constant using the triangle wave generated by the triangle wave formation circuit.

In this configuration, when there is no large difference between the power supply voltage and the output voltage, it is possible to increase the amplitude of the triangle wave and thereby reduce the ripple of the output voltage. Further, when there is a certain degree of difference between the power supply voltage and the output voltage, it is possible to reduce the amplitude of the triangle wave and thereby increase the speed of response. It is thus possible to increase the accuracy of the output voltage and improve the transient response characteristics.

A second exemplary aspect of an embodiment of the present invention is a triangle wave generator that includes a first comparator to compare a power supply voltage with an input voltage, a capacitor including a first electrode connected to ground and a second electrode, and a charge and discharge circuit to charge and discharge the second electrode of the capacitor and change amplitude of a triangle wave according to an output signal of the first comparator.

In this configuration, when there is no large difference between the power supply voltage and the output voltage, it is possible to increase the amplitude of the triangle wave. Therefore, by applying the triangle wave generator to the switching regulator, it is possible to reduce the ripple of the output voltage. Further, when there is a certain degree of difference between the power supply voltage and the output voltage, it is possible to reduce the amplitude of the triangle wave and thereby increase the speed of response. It is thus possible to increase the accuracy of the output voltage and improve the transient response characteristics.

According to the exemplary aspects of an embodiment of the present invention described above, it is possible to provide a triangle wave generator and a switching regulator that enable reduction of the ripple and improvement of the output voltage accuracy and the transient response characteristics.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a view showing the configuration of a triangle wave generator according to an exemplary embodiment;

FIG. 2 is a view showing the configuration of a variable reference voltage circuit used in the triangle wave generator according to the exemplary embodiment;

FIG. 3 is a timing chart to describe the operation of the triangle wave generator when the output of a first comparator is Lo (operation A);

FIG. 4 is a timing chart to describe the operation of the triangle wave generator when the output of the first comparator is Hi (operation B);

FIG. 5 is a view showing the configuration of a switching regulator using the triangle wave generator according to the exemplary embodiment;

FIG. 6 is a view to describe the total gain of the switching regulator shown in FIG. 5;

FIG. 7 is a view showing the configuration of a switching regulator using a triangle wave generator according to prior art;

FIG. 8 is a view showing the configuration of the triangle wave generator according to prior art;

FIG. 9 is a view showing an example of a triangle wave generated in the triangle wave generator according to prior art; and

FIG. 10 is a view to describe an issue.

### DETAILED DESCRIPTION OF THE EXEMPLARY EMBODIMENTS

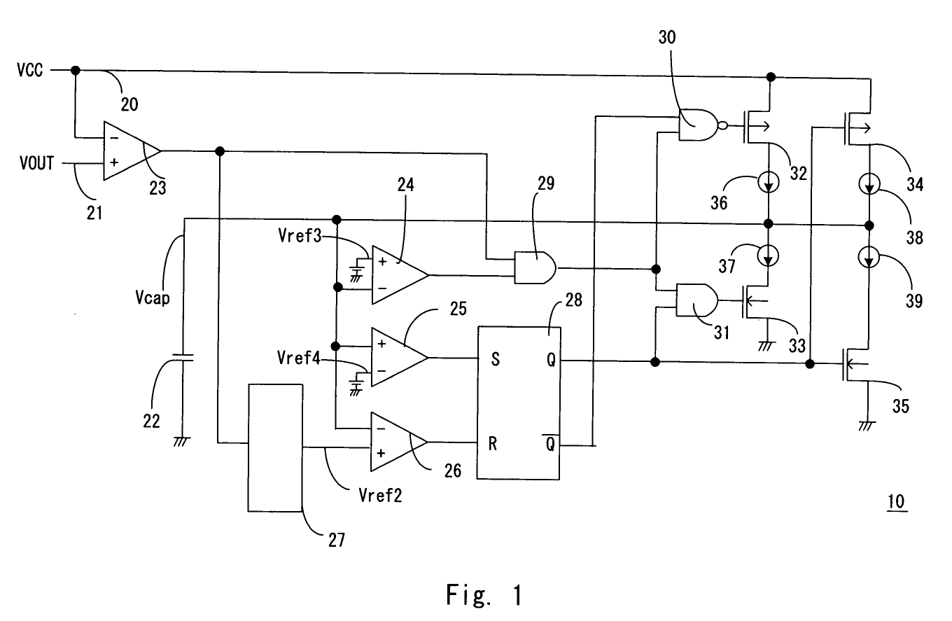

A triangle wave generator according to an exemplary embodiment of the present invention is described hereinafter with reference to FIG. 1. FIG. 1 is a view showing the configuration of a triangle wave generator 10 according to the exemplary embodiment. Referring to FIG. 1, the triangle wave generator 10 according to the exemplary embodiment includes a capacitor 22, a first comparator 23, a second comparator 24, a third comparator 25, a fourth comparator 26, a variable reference voltage circuit 27, an RS flip-flop 28, a first dual input AND circuit 29, a dual input NAND circuit 30, a second dual input AND circuit 31, a first PMOS 32, a first NMOS 33, a second PMOS 34, a second NMOS 35, a first charge current source 36, a first discharge current source 37, a second charge current source 38, and a second discharge current source 39.

One electrode of the capacitor 22 is connected to GND, and the other electrode (Vcap) is connected to the − input of the second comparator 24, the + input of the third comparator 25, the − input of the fourth comparator 26, the drain of the first charge current source 36, the drain of the first discharge current source 37, the drain of the second charge current source 38, and the drain of the second discharge current source 39.

The − input of the third comparator 25 is connected to a reference voltage Vref4, and the output of the third comparator 25 is connected to the S (set) input of the RS flip-flop 28. The + input of the fourth comparator 26 is connected to the output (variable reference voltage Vref2) of the variable reference voltage circuit 27. The variable reference voltage circuit 27 is connected to the output of the first comparator 23 with offset. The first comparator 23 compares a power supply voltage VCC 20 with a switching regulator output voltage VOUT 21. The first comparator 23 has an offset voltage at the + input or the − input.

The output of the fourth comparator 26 is connected to the R (reset) input of the RS flip-flop 28. The + input of the second comparator 24 is connected to a reference voltage Vref3, and the output of the second comparator 24 is connected to one input of the first dual input AND circuit 29. The other input of the first dual input AND circuit 29 is connected to the output of the first comparator 23. The output of the first dual input AND circuit 29 is connected to one input of the dual input NAND circuit 30 and one input of the second dual input AND circuit 31.

The other input of the dual input NAND circuit 30 is connected to the output Q-bar of the RS flip-flop 28, and the output of the dual input NAND circuit 30 is connected to the gate terminal of the first PMOS 32. The source terminal of the first PMOS 32 is connected to the power supply voltage VCC 20, and the drain terminal of the first PMOS 32 is connected to the source of the first charge current source 36. The other input of the second dual input AND circuit 31 is connected to the output Q of the RS flip-flop 28.

The output of the second dual input AND circuit 31 is connected to the gate terminal of the first NMOS 33. The source terminal of the first NMOS 33 is connected to GND, and the drain terminal of the first NMOS 33 is connected to the source of the first discharge current source 37. The output Q of the RS flip-flop 28 is connected to the gate terminal of the second NMOS 35 and the gate terminal of the second PMOS 34. The source terminal of the second NMOS 35 is connected to GND, and the drain terminal of the second NMOS 35 is connected to the source of the second discharge current source 39. The source terminal of the second PMOS 34 is connected to the power supply voltage VCC 20, and the drain terminal of the second PMOS 34 is connected to the source of the second charge current source 38.

The first PMOS 32, the first NMOS 33, the second PMOS 34, the second NMOS 35, the first charge current source 36, the first discharge current source 37, the second charge current source 38 and the second discharge current source 39 serve as a charge and discharge circuit that charges or discharges one electrode of the capacitor 22 to change the amplitude of the triangle wave. Further, the second comparator 24, the third comparator 25, the fourth comparator 26 and the RS flip-flop 28 form a switching circuit that switches charge and discharge of the charge and discharge circuit based on the output signal of the first comparator 23. The charge and discharge circuit and the switching circuit are included in a triangle wave formation circuit that changes the amplitude of the triangle wave.

The charge and discharge circuit includes a first charge and discharge unit that switches charge and discharge of the capacitor 22 based on the output signal of the first comparator 23 and the switching signal from the switching circuit, and a second charge and discharge unit that switches charge and discharge of the capacitor 22 based on the switching signal from the switching circuit. The first charge and discharge unit includes the first PMOS 32, the first NMOS 33, the first charge current source 36 and the first discharge current source 37. The second charge and discharge unit includes the second PMOS 34, the second NMOS 35, the second charge current source 38 and the second discharge current source 39.

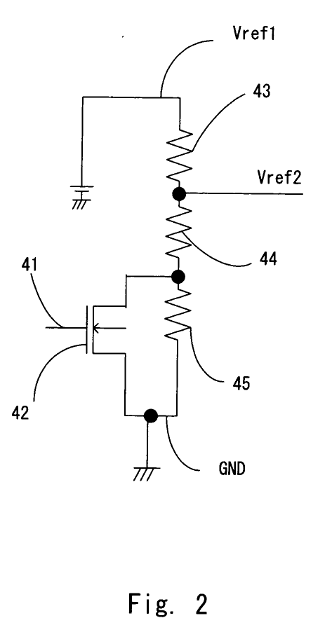

The circuit configuration of the variable reference voltage circuit 27 is described hereinafter with reference to FIG. 2. FIG. 2 is a view showing the configuration of the variable reference voltage circuit 27. Referring to FIG. 2, the variable reference voltage circuit 27 includes a third NMOS 42, a first resistor 43, a second resistor 44 and a third resistor 45. One end of the first resistor 43 is connected to Vref1, and the other end of the first resistor 43 is connected to one end of the second resistor 44. The other end of the second resistor 44 is connected to one end of the third resistor 45, the other end of which is connected to GND, and the drain terminal of the third NMOS 42. The gate terminal 41 of the third NMOS 42 is connected to the output of the first comparator 23, and the source terminal of the third NMOS 42 is connected to GND.

The operation of the variable reference voltage circuit 27 shown in FIG. 2 is described hereinafter. When the output voltage of the first comparator 23 is Lo, the third NMOS 42 is OFF, and therefore the potential of Vref2 can be obtained by the following expression (4) where the resistance of the first resistor 43 is R12, the resistance of the second resistor 44 is R13 and the resistance of the third resistor 45 is R14:

Vref2=Vref1×(R13+R14)÷(R12+R13+R14) (4)

On the other hand, when the output voltage of the first comparator 23 is Hi, the third NMOS 42 is ON, and therefore the potential of Vref2 can be obtained by the following expression (5):

Vref2=Vref1×R13÷(R12+R13) (5)

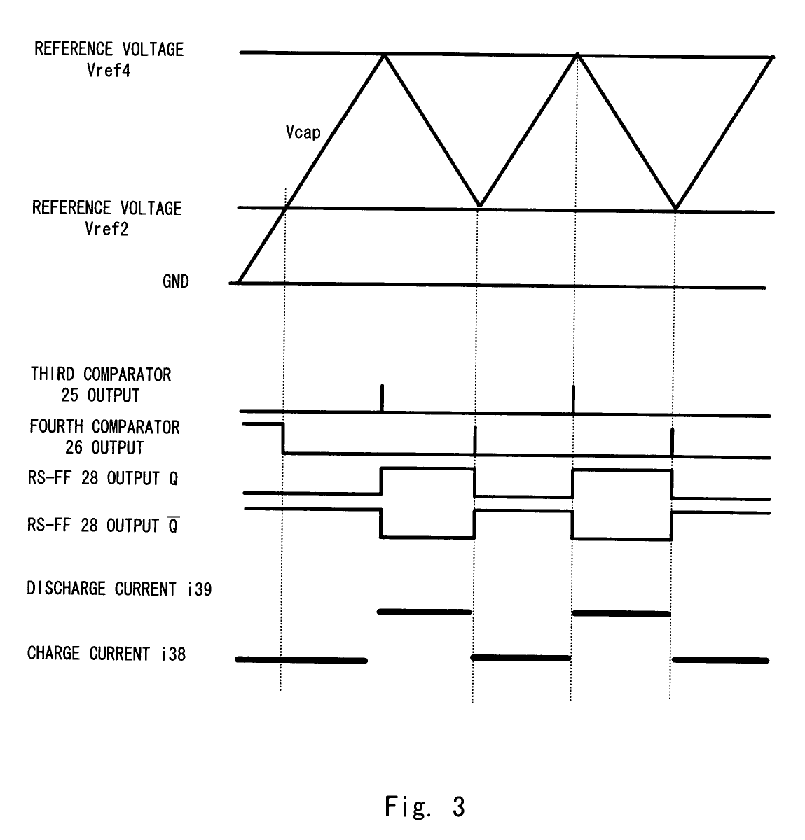

Hereinafter, the operation of the triangle wave generator 10 when the output voltage of the first comparator 23 is Lo is referred to as the operation A, and the operation when it is Hi is referred to as the operation B. The operation A is first described with reference to FIG. 3. FIG. 3 is a timing chart to describe the operation A of the triangle wave generator 10.

The power supply voltage VCC 20, the switching regulator output voltage VOUT 21 and an offset voltage Voff of the first comparator 23 have the relationship represented by the following expression (6):

VOUT21>VCC20+Voff (6)

Further, the reference voltage Vref4 and the reference voltage Vref1 have the relationship represented by the following expression (7):

Vref4>Vref1 (7)

When the output voltage of the first comparator 23 that compares the output voltage VOUT 21 with the power supply voltage VCC 20 is Lo, the output of the first dual input AND circuit 29 is always Lo. Accordingly, the first PMOS 32 is OFF, and the first charge current source 36 does not let a current flow. Further, the first NMOS 33 is also OFF, and the first discharge current source 37 does not let a current flow.

When the voltage of the capacitor 22, which is the potential of Vcap, is GND level, the output of the fourth comparator 26 is Hi, and the output of the third comparator 25 is Lo. Accordingly, the output Q of the RS flip-flop 28 is Lo. Then, the second PMOS 34 turns ON, and the second charge current source 38 lets a current flow, and the capacitor 22 is charged. The potential of Vcap thereby increases as represented by the following expression (8) where the current flowing through the second charge current source 38 is i38 and the capacitance of the capacitor 22 is C22:

Vcap=Q÷C=i38×t÷C22 (8)

If the potential of Vcap becomes higher than the reference voltage Vref4, the output of the third comparator 25 changes from Lo to Hi. Because the output of the fourth comparator 26 is Lo, the output Q of the RS flip-flop 28 changes from Lo to Hi. When the output Q of the RS flip-flop 28 becomes Hi, the second PMOS 34 turns OFF, and the charge by the second charge current source 38 thereby stops.

On the other hand, the second NMOS 35 turns ON, and the potential of Vcap of the capacitor 22 is discharged by the second discharge current source 39. The potential of Vcap decreases as represented by the following expression (9) where the current of the second discharge current source 39 is i39:

Vcap=Vref4−i39×t÷C22 (9)

If the potential of Vcap becomes lower than the variable reference voltage Vref2, the output of the fourth comparator 26 changes from Lo to Hi. Because the output of the third comparator 25 remains Lo, the output Q of the RS flip-flop 28 changes from Hi to Lo. When the output Q of the RS flip-flop 28 becomes Lo, the second NMOS 35 turns OFF, and the discharge by the second discharge current source 39 thereby stops.

On the other hand, the second PMOS 34 turns ON, and the potential of Vcap of the capacitor 22 is charged by the second charge current source 38 and it thereby increases as represented by the following expression (10)

Vcap=Vref2+i38×t÷C22 (10)

If the potential of Vcap becomes higher than the reference voltage Vref4, the output of the third comparator 25 changes from Lo to Hi. Because the output of the fourth comparator 26 remains Lo, the output Q of the RS flip-flop 28 changes from Lo to Hi. The triangle wave as shown in FIG. 3 is thereby generated for Vcap.

As described above, the triangle wave generator 10 according to the exemplary embodiment enables reduction of the amplitude of the triangle wave when there is a certain degree of difference between the power supply voltage VCC 20 and the switching regulator output voltage VOUT 21. By supplying such a triangle wave to the switching regulator, it is possible to increase the speed of response, increase the accuracy of the output voltage and improve the transient response characteristics.

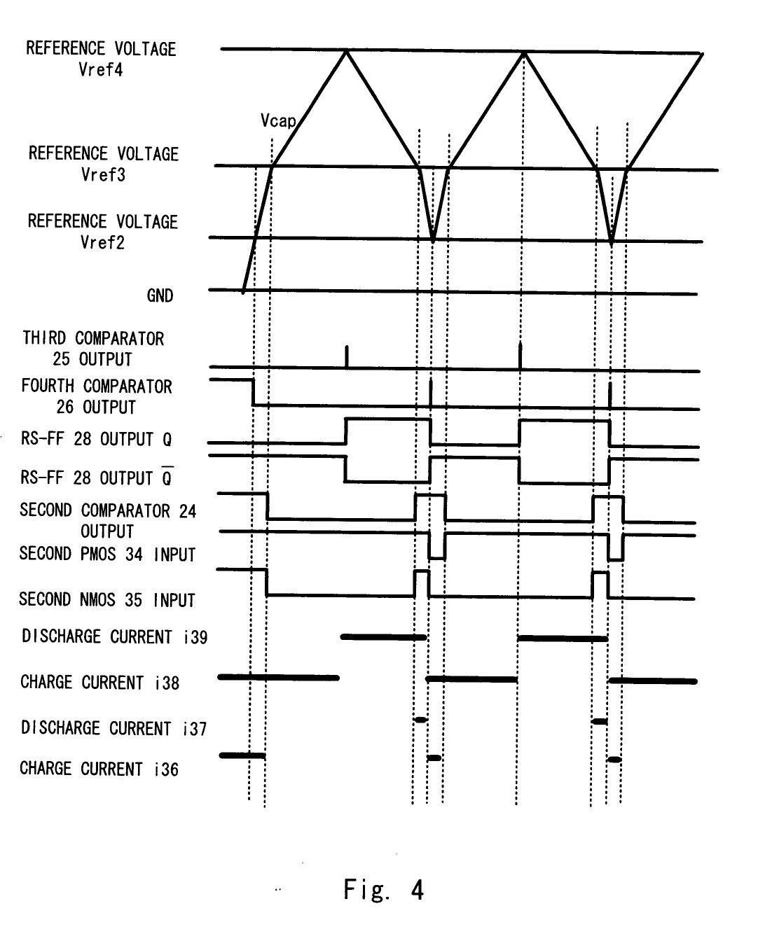

Next, the operation B is described with reference to FIG. 4. The power supply voltage VCC 20, the output voltage VOUT 21 and the offset voltage Voff of the first comparator 23 have the relationship represented by the following expression (11):

VOUT21<VCC20+Voff (11)

Further, the variable reference voltage Vref2, the reference voltage Vref3 and the reference voltage Vref4 have the relationship represented by the following expression (12):

Vref4>Vref3>Vref2 (12)

When the output voltage of the first comparator 23 that compares the output voltage VOUT 21 with the power supply voltage VCC 20 is Hi and when the output of the second comparator 24 is Hi, the output of the first dual input AND circuit 29 is Hi. In this state, if the Q-bar of the RS flip-flop 28 is Hi, the first PMOS 32 turns ON, and the first charge current source 36 lets a charge current flow. Further, if the output Q of the RS flip-flop 28 is Hi, the first NMOS 33 turns ON, and the first discharge current source 37 lets a discharge current flow.

When the potential of Vcap is GND level, the output of the fourth comparator 26 is Hi. Because the output of the third comparator 25 remains Lo, the output Q of the RS flip-flop 28 is Lo. Then, the second PMOS 34 turns ON, and a charge current is supplied from the second charge current source 38 and the capacitor 22 is thereby charged.

Further, when the potential of Vcap is GND level, the output of the second comparator 24 is Hi. Then, the first PMOS 32 turns ON, and the capacitor 22 is charged by the first charge current source 36. The potential of Vcap thereby increases as represented by the following expression (13) where the current of the first charge current source 36 is i36 and the current of the second charge current source 38 is i38:

Vcap=(i38+i36)×t÷C22 (13)

If the potential of Vcap becomes higher than the reference voltage Vref3, the output of the second comparator 24 changes from Hi to Lo, and the first PMOS 32 turns OFF, and the first charge current source 36 thereby stops.

On the other hand, because the second PMOS 34 keeps ON, the capacitor 22 is charged by the second charge current source 38, and the potential of Vcap is obtained by the following expression (14):

Vcap=Vref3+i38×t÷C22 (14)

If the potential of Vcap becomes higher than the reference voltage Vref4, the output of the third comparator 25 changes from Lo to Hi. Because the output of the fourth comparator 26 remains Lo, the output Q of the RS flip-flop 28 changes from Lo to Hi. When the output Q of the RS flip-flop 28 becomes Hi, the second PMOS 34 turns OFF, and the charge by the second charge current source 38 thereby stops.

On the other hand, the second NMOS 35 turns ON, and the potential of Vcap is discharged by the second discharge current source 39, and thereby the potential of Vcap decreases as represented by the following expression (15):

Vcap=Vref4−i39×t÷C22 (15)

If the potential of Vcap becomes lower than the reference voltage Vref3, the output of the second comparator 24 changes from Lo to Hi, the first NMOS 33 turns ON, and a discharge current is supplied from the first discharge current source 37. The potential of Vcap at this time is obtained by the following expression (16):

Vcap=Vref3−(i39+i37)×t÷C22 (16)

If the potential of Vcap further decreases to become lower than the variable reference voltage Vref2, the output of the fourth comparator 26 changes from Lo to Hi. Because the output of the third comparator 25 remains Lo, the output Q of the RS flip-flop 28 changes from Hi to Lo. The second NMOS 35 and the first NMOS 33 thereby turn OFF, and therefore the discharge by the second discharge current source 39 and the first discharge current source 37 stops.

On the other hand, the second PMOS 34 and the first PMOS 32 turn ON, and the capacitor 22 is charged by the second charge current source 38 and the first charge current source 36, and therefore the potential of Vcap increases as represented by the following expression (17):

Vcap=Vref2+(i36+i38)×t÷C22 (17)

If the potential of Vcap becomes higher than the reference voltage Vref3, the output of the second comparator 24 changes from Hi to Lo, the first PMOS 32 turns OFF, and the first charge current source 36 thereby stops. The potential of Vcap of the capacitor 22 at this time is obtained by the following expression (18):

Vcap=Vref3+i38×t÷C22 (18)

The triangle wave with large amplitude is thereby generated as shown in FIG. 4.

As described above, the triangle wave generator 10 according to the exemplary embodiment enables supply of the triangle wave with large amplitude when the power supply voltage VCC 20 and the switching regulator output voltage VOUT 21 are not largely different from each other. By supplying such a triangle wave to the switching regulator, it is possible to output a stable pulse in each cycle of the triangle wave to thereby reduce the ripple voltage.

FIG. 5 shows a voltage feedback PWM step-up switching regulator using the triangle wave generator 10 according to the exemplary embodiment of the present invention. Referring to FIG. 5, the switching regulator according to the exemplary embodiment includes the triangle wave generator 10, a first FB (feedback) resistor 51, a second FB (feedback) resistor 52, an error amplifier 55, a PWM comparator 57, a pre-driver stage 58, a switching NMOS transistor 59, an inductor 60, a shotkey diode 61, a capacitor 62 and a load 63.

The switching regulator output voltage VOUT 21 is connected to one electrode of the capacitor 62, the other electrode of which is connected to GND, the cathode terminal of the rectifier shotkey diode 61, one end of the first FB resistor 51, the triangle wave generator 10, and the load 63. The other end of the first FB resistor 51 is connected to one end of the second FB resistor 52, the other end of which is connected to GND. A node 53 between the first FB resistor 51 and the second FB resistor 52 is connected to the − input of the error amplifier 55. The + input of the error amplifier 55 is connected to a reference voltage Vref54.

The output of the error amplifier 55 is connected to the + input of the PWM comparator 57, and the − input of the PWM comparator 57 is connected to the output of the triangle wave generator 10. The output of the PWM comparator 57 is connected to the input of the pre-driver stage 58. The output of the pre-driver stage 58 is connected to the gate terminal of the switching NMOS transistor 59 inside the IC. The switching NMOS transistor 59 may be placed outside the IC. The source terminal of the switching NMOS transistor 59 is connected to GND, and the drain terminal of the switching NMOS transistor 59 is connected to the power supply voltage VCC 20.

The power supply voltage VCC 20 is connected to the triangle wave generator 10 and one end of the inductor 60. The other end of the inductor 60 is connected to the anode terminal of the shotkey diode 61. In the switching regulator according to the exemplary embodiment, the switching regulator output voltage VOUT 21 is maintained substantially constant using the triangle wave generated in the triangle wave generator 10.

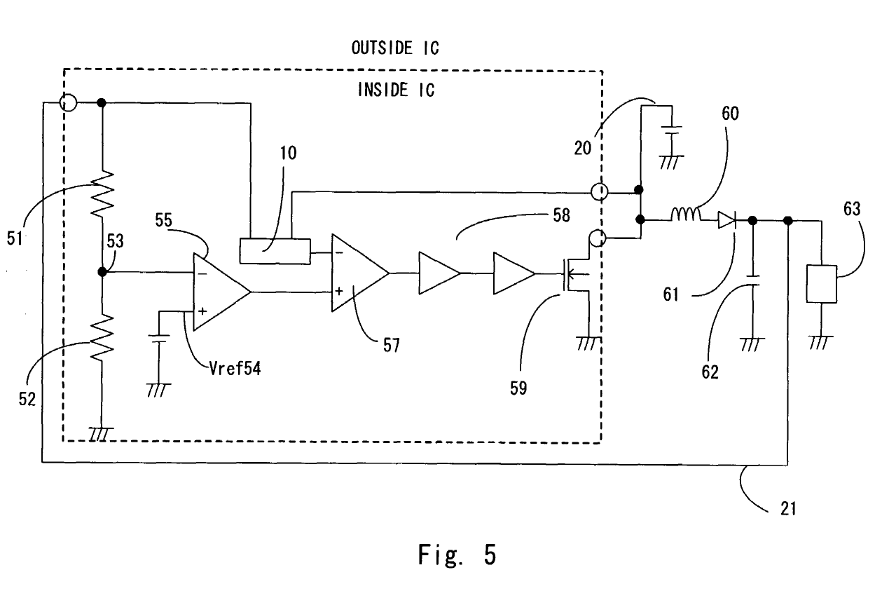

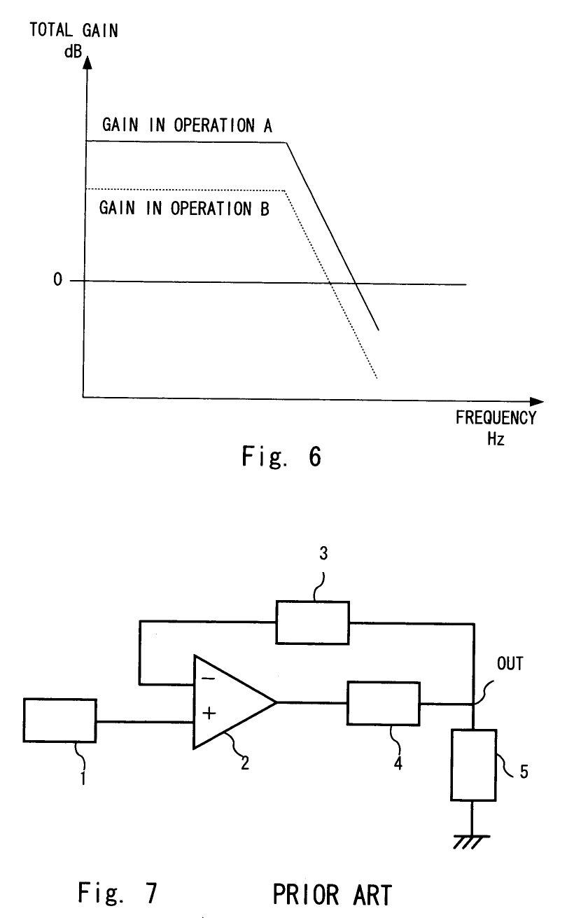

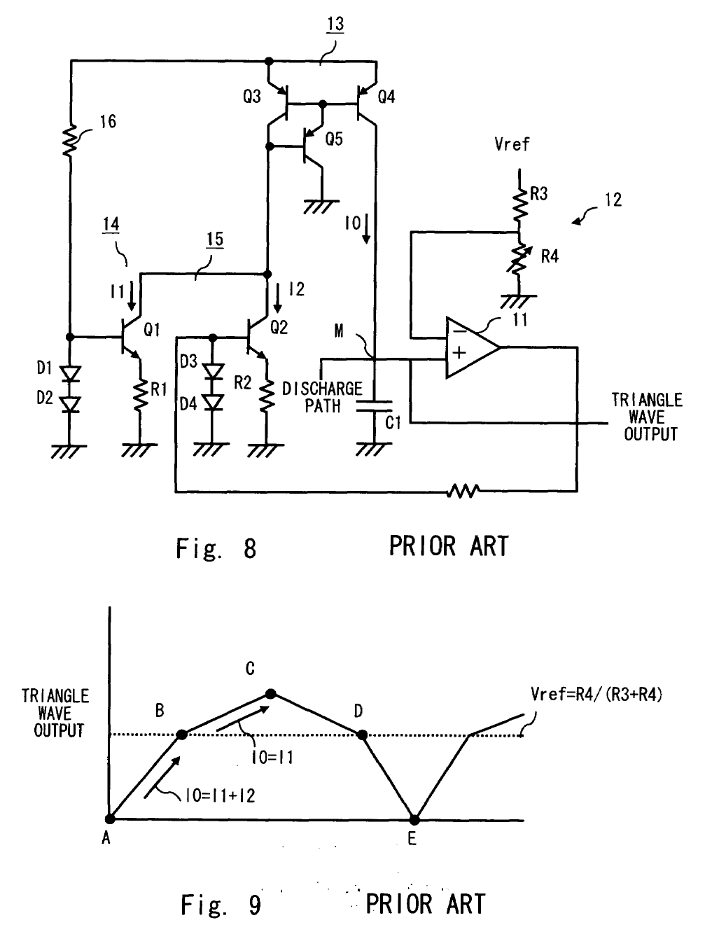

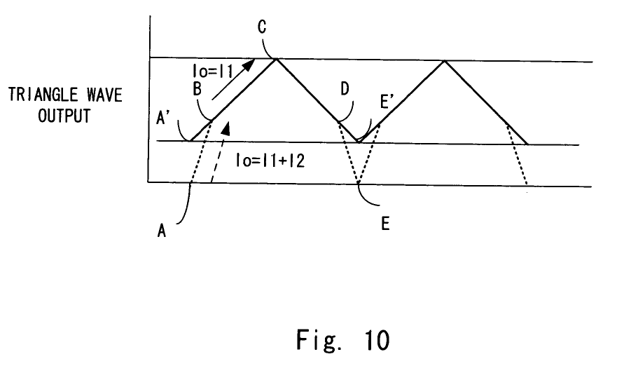

FIG. 6 shows a result of frequency characteristics with respect to the total gain of the switching regulator in the operation A when the output voltage of the first comparator 23 that compares the power supply voltage VCC 20 with the switching regulator output voltage VOUT 21 is Lo, and the total gain of the switching regulator in the operation B when the output voltage of the first comparator 23 is Hi.

As shown in FIG. 6, when the output voltage of the first comparator 23 is Lo (in the operation A), the total gain can be increased by supplying the triangle wave with small amplitude. On the other hand, when the output voltage of the first comparator 23 is Hi (in the operation B), the total gain can be decreased by supplying the triangle wave with large amplitude.

Therefore, when there is a large enough difference between the power supply voltage VCC 20 and the switching regulator output voltage VOUT 21, it is possible to improve the output voltage accuracy and the transient response characteristics by supplying the triangle wave with small amplitude. On the other hand, when there is no large difference between the power supply voltage VCC 20 and the switching regulator output voltage VOUT 21, it is possible to reduce the total gain of the switching regulator by supplying the triangle wave with large amplitude. It is thereby possible to output a stable pulse in each cycle of the triangle wave and reduce the ripple voltage without using highly technical circuits such as a high-speed error amplifier and a high-speed PWM comparator.

As described in the foregoing, by changing the amplitude of the triangle wave to be input to the PWM comparator 57 according to a difference between the power supply voltage VCC 20 and the switching regulator output voltage VOUT 21, it is possible to reduce the ripple or improve the output voltage accuracy and the transient response characteristics.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A switching regulator comprising:
a first comparator to compare a power supply voltage with an output voltage of the switching regulator; and
a triangle wave formation circuit to change amplitude of a triangle wave according to an output signal of the first comparator, wherein
the output voltage is maintained substantially constant using the triangle wave generated by the triangle wave formation circuit.

2. The switching regulator according to claim 1, further comprising:
a variable reference voltage circuit to generate a variable reference voltage varying with the output signal of the first comparator, wherein
the amplitude of the triangle wave is changed based on the variable reference voltage.

3. The switching regulator according to claim 1, wherein the triangle wave formation circuit comprises:
a capacitor including a first electrode connected to ground and a second electrode;
a charge and discharge circuit to charge and discharge the second electrode of the capacitor and change the amplitude of the triangle wave; and
a switching circuit to switch charge and discharge of the charge and discharge circuit based on the output signal of the first comparator.

4. The switching regulator according to claim 3, wherein the charge and discharge circuit comprises:
a first charge and discharge unit to switch charge and discharge of the capacitor based on the output signal of the first comparator and a switching signal from the switching circuit; and
a second charge and discharge unit to switch charge and discharge of the capacitor based on the switching signal from the switching circuit.

5. The switching regulator according to claim 3, wherein the switching circuit comprises:
a second comparator with a + input connected to the variable reference voltage generated by the variable reference voltage circuit and a − input connected to the second electrode of the capacitor;
a third comparator with a + input connected to the second electrode of the capacitor and a − input connected to a first reference voltage;
a fourth comparator with a − input connected to the second electrode of the capacitor and a + input connected to a second reference voltage; and
a reset-set flip-flop with a set terminal connected to an output of the third comparator and a reset terminal connected to an output of the second comparator.

6. The switching regulator according to claim 5, wherein the charge and discharge circuit comprises:
a first current source connected so as to charge the second electrode of the capacitor and controlled by an output of the first comparator, an output of the fourth comparator and an output Q-bar of the RS flip-flop;
a second current source connected so as to discharge the second electrode of the capacitor and controlled by the output of the first comparator, the output of the fourth comparator and an output Q of the RS flip-flop;
a third current source connected so as to charge the second electrode of the capacitor and controlled by the output Q of the RS flip-flop; and
a fourth current source connected so as to discharge the second electrode of the capacitor and controlled by the output Q of the RS flip-flop.

7. The switching regulator according to claim 1, wherein
one of a + input and a − input of the first comparator has an offset voltage.

8. A triangle wave generator comprising:
a first comparator to compare a power supply voltage with an input voltage;
a capacitor including a first electrode connected to ground and a second electrode; and
a charge and discharge circuit to charge and discharge the second electrode of the capacitor and change amplitude of a triangle wave according to an output signal of the first comparator.

9. The triangle wave generator according to claim 8, further comprising:
a variable reference voltage circuit to generate a variable reference voltage varying with the output signal of the first comparator, wherein
the amplitude of the triangle wave is changed based on the variable reference voltage.

10. The triangle wave generator according to claim 8, further comprising:
a switching circuit to switch charge and discharge of the charge and discharge circuit based on the output signal of the first comparator.

11. The triangle wave generator according to claim 8, further comprising:
a second comparator with a + input connected to a variable reference voltage varying with the output signal of the first comparator and a − input connected to the second electrode of the capacitor;
a third comparator with a + input connected to the second electrode of the capacitor and a − input connected to a first reference voltage;
a fourth comparator with a − input connected to the second electrode of the capacitor and a + input connected to a second reference voltage;
a reset-set flip-flop with a set terminal connected to an output of the third comparator and a reset terminal connected to an output of the second comparator;
a first current source connected so as to charge the second electrode of the capacitor and controlled by an output of the first comparator, an output of the fourth comparator and an output Q-bar of the RS flip-flop;
a second current source connected so as to discharge the second electrode of the capacitor and controlled by the output of the first comparator, the output of the fourth comparator and an output Q of the RS flip-flop;
a third current source connected so as to charge the second electrode of the capacitor and controlled by the output Q of the RS flip-flop; and
a fourth current source connected so as to discharge the second electrode of the capacitor and controlled by the output Q of the RS flip-flop.
